(19) United States
(12) Patent Application Publication
(10) Pub. No.: US 2023/0268311 A1
(43) Pub. Date: Aug. 24, 2023

(54) SEMICONDUCTOR DEVICE, AND PRODUCTION METHOD FOR SEMICONDUCTOR DEVICE

(71) Applicant: ROHM CO., LTD., Kyoto-shi, Kyoto (JP)

(72) Inventor: Koshun SAITO, Kyoto-shi, Kyoto (JP)

(21) Appl. No.: 18/005,264

(22) PCT Filed: Jul. 5, 2021
(86) PCT No.: PCT/JP2021/025260

§ 371 Date: Jan. 12, 2023

(30) Foreign Application Priority Data
Jul. 16, 2020 (JP) 2020-122040

(51) Int. Cl. H01L 23/00; H01L 23/31; H01L 23/495

(52) U.S. Cl. CPC H01L 24/73; H01L 24/05; H01L 24/06; H01L 24/29; H01L 24/32; H01L 24/37; H01L 24/40; H01L 24/45; H01L 24/48; H01L 24/83; H01L 24/84; H01L 24/92; H01L 23/3107; H01L 23/49568; H01L 23/49513; H01L 2924/10272; H01L 2924/1033; H01L 2924/13091; H01L 2224/05553; H01L 2224/05552; H01L 2224/06051; H01L 2224/0603; H01L 2224/06181; H01L 2224/29111; H01L 2224/29116; H01L 2224/32245; H01L 2224/37147; H01L 2224/40108; H01L 2224/40245; H01L 2224/40499; H01L 2924/0105; H01L 2224/45124; H01L 2224/48091; H01L 2224/48108; H01L 2224/48245; H01L 2224/83815; H01L 2224/83192; H01L 2224/84815; H01L 2224/92157; H01L 2224/92246; H01L 2224/73221; H01L 2224/73263; H01L 2224/73265

(57) ABSTRACT

A semiconductor device includes a die pad, a semiconductor element, a joining layer, a first conductive member, and a second conductive member. The semiconductor element has a first electrode opposing an obverse surface of the die pad, and a second electrode and a third electrode that are opposite to the first electrode in a thickness direction. The first electrode is electrically joined to the obverse surface. The joining layer electrically joins the first electrode and the obverse surface to each other. The first conductive member is electrically joined to the second electrode. The second conductive member is electrically joined to the third electrode. The area of the third electrode is smaller than the area of the second electrode as viewed along the thickness direction. The Young's modulus of the second conductive member is smaller than the Young's modulus of the first conductive member.

### TECHNICAL FIELD

The present disclosure relates to a semiconductor device provided with a semiconductor element such as a MOSFET, while also relating to a method for manufacturing such a semiconductor device.

### BACKGROUND ART

Semiconductor elements such as MOSFETs that convert a current based on an electric signal are widely known. Such semiconductor elements are used, for example, in electronic apparatuses provided with a power converting circuit such as a DC-DC converter. Patent Document 1 discloses an example of a semiconductor device to which a MOSFET is mounted. The semiconductor device includes a drain lead to which a power source voltage is applied, a gate lead for inputting an electric signal to the MOSFET, and a source lead through which a current that corresponds to the power source voltage flows after being converted based on the electric signal. The MOSFET includes a drain electrode that is electrically connected to the drain lead, a gate electrode that is electrically connected to the gate lead, and a source electrode that is electrically connected to the source lead. The drain electrode is electrically joined to the drain lead via solder. The gate electrode and the gate lead and the source electrode and the source lead are electrically joined to each other by a metal clip, respectively. Accordingly, a larger current can flow through the semiconductor device.

Recent years have seen the spread of semiconductor devices provided with a MOSFET that includes a compound semiconductor substrate made of a material such as silicon carbide. Compared to conventional MOSFETS, these MOSFETs have the benefit of enabling conversion efficiency of a current to be further improved, while further reducing the size of the device. Regarding the semiconductor device disclosed in Patent Document 1, if such a MOSFET is employed, when electrically joining the drain electrode to the drain lead by using solder, there are cases where the position of the MOSFET is shifted relative to the drain lead. This is due to the MOSFET being comparatively light and the solder being melted through reflow. Furthermore, the area of the gate electrode is smaller than the area of the source electrode. Thus, if the position of the MOSFET is shifted relative to the die pad, a major reduction in the joining area of the metal clip to the gate electrode is of particular concern. This leads to degradation of the joining state of the metal clip to the gate electrode, and thus is a factor in a reduction in the yield of the semiconductor device.

### PRIOR ART DOCUMENTS

### Patent Document

Patent Document 1: JP-A-2001-274206

### SUMMARY OF THE INVENTION

### Problem to be Solved by the Invention

In light of the foregoing, the present disclosure is directed at providing a semiconductor device that can improve the joining state of a conductive member to each electrode of a semiconductor element while supporting a larger current, and a manufacturing method for the same.

### Means for Solving the Problem

A semiconductor device provided according to a first aspect of the present disclosure includes: a die pad that has an obverse surface facing in a thickness direction; a semiconductor element that has a first electrode opposing the obverse surface, and a second electrode and a third electrode that are opposite to the first electrode in the thickness direction and are spaced apart from each other, where the first electrode is electrically joined to the obverse surface; a first joining layer that electrically joins the first electrode and the obverse surface to each other; a first conductive member electrically joined to the second electrode; and a second conductive member electrically joined to the third electrode. The area of the third electrode is smaller than the area of the second electrode as viewed along the thickness direction, and the Young's modulus of the second conductive member is smaller than the Young's modulus of the first conductive member.

A method of manufacturing a semiconductor device provided according to a second aspect of the present invention includes: disposing a conductive joining material on a die pad that has an obverse surface facing in a thickness direction; disposing a semiconductor element on the joining material, where the semiconductor element has a first electrode, a second electrode and a third electrode, with the first electrode and the second electrode being opposite to each other in the thickness direction, with the third electrode being provided on a same side as the second electrode in the thickness direction and spaced apart from the second electrode, and with the first electrode facing the joining material; electrically joining the first electrode to the obverse surface by melting and solidifying the joining material; electrically joining the first conductive member to the second electrode; and electrically joining the second conductive member to the third electrode. The third electrode is smaller in area than the second electrode as viewed along the thickness direction, and the second conductive member is smaller in Young's modulus than the first conductive member.

### Advantages of the Invention

With the above semiconductor device and manufacturing method for the same according to the present disclosure, the joining state of a conductive member to each electrode of a semiconductor element can be improved while supporting a larger current.

Other features and advantages of the present disclosure will be apparent from the following detailed description with reference to the attached diagrams.

### BRIEF DESCRIPTION OF DRAWINGS

FIG. 1 is a perspective view showing a semiconductor device according to a first embodiment of the present disclosure.

FIG. 2 is a plan view showing the semiconductor device shown in FIG. 1.

FIG. 3 is a plan view corresponding to FIG. 2, in which sealing resin is shown in a transparent manner.

FIG. 4 is a bottom view of the semiconductor device shown in FIG. 1.

FIG. 5 is a front view of the semiconductor device shown in FIG. 1.

FIG. 6 is a right-side view of the semiconductor device shown in FIG. 1.

FIG. 7 is a cross-sectional view taken along line VII-VII in FIG. 3.

FIG. 8 is a cross-sectional view taken along line VIII-VIII in FIG. 3.

FIG. 9 is a cross-sectional view taken along line IX-IX in FIG. 3.

FIG. 10 is a cross-sectional view taken along line X-X in FIG. 3.

FIG. 11 is a partially enlarged view of FIG. 3.

FIG. 12 is a partially enlarged view of FIG. 7.

FIG. 13 is a partially enlarged view of FIG. 7.

FIG. 14 is a partially enlarged view of FIG. 8.

FIG. 15 is a plan view for describing a manufacturing step of the semiconductor device shown in FIG. 1.

FIG. 16 is a plan view for describing a manufacturing step of the semiconductor device shown in FIG. 1.

FIG. 17 is a plan view for describing a manufacturing step of the semiconductor device shown in FIG. 1.

FIG. 18 is a partially enlarged cross-sectional view for describing a manufacturing step of the semiconductor device shown in FIG. 1.

FIG. 19 is a plan view for describing a manufacturing step of the semiconductor device shown in FIG. 1.

FIG. 20 is a partially enlarged cross-sectional view for describing a manufacturing step of the semiconductor device shown in FIG. 1.

FIG. 21 is a partially enlarged cross-sectional view for describing a manufacturing step of the semiconductor device shown in FIG. 1.

FIG. 22 is a plan view for describing a manufacturing step of the semiconductor device shown in FIG. 1.

FIG. 23 is a plan view for describing a manufacturing step of the semiconductor device shown in FIG. 1.

FIG. 24 is a plan view for describing the operation and effects of the semiconductor device shown in FIG. 1.

### MODE FOR CARRYING OUT THE INVENTION

Embodiments of the present disclosure will be described below with reference to the appended drawings.

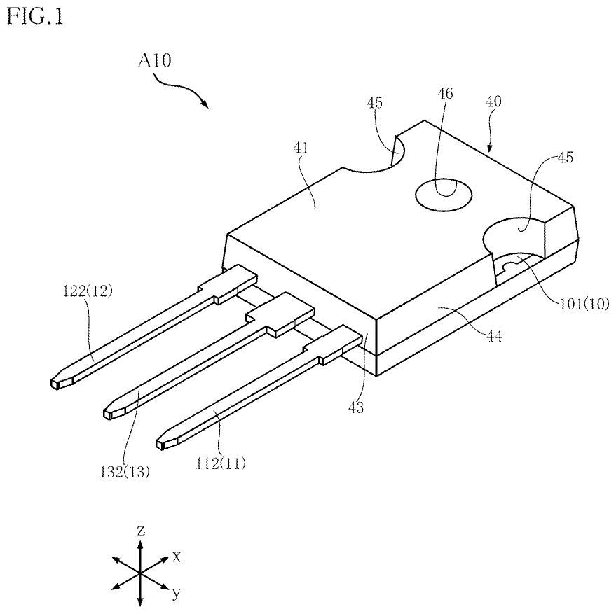

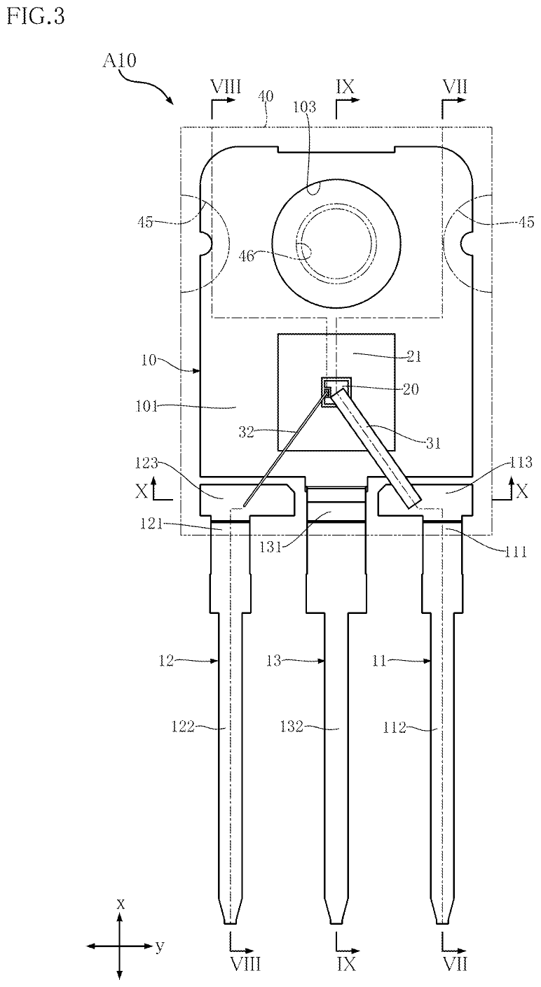

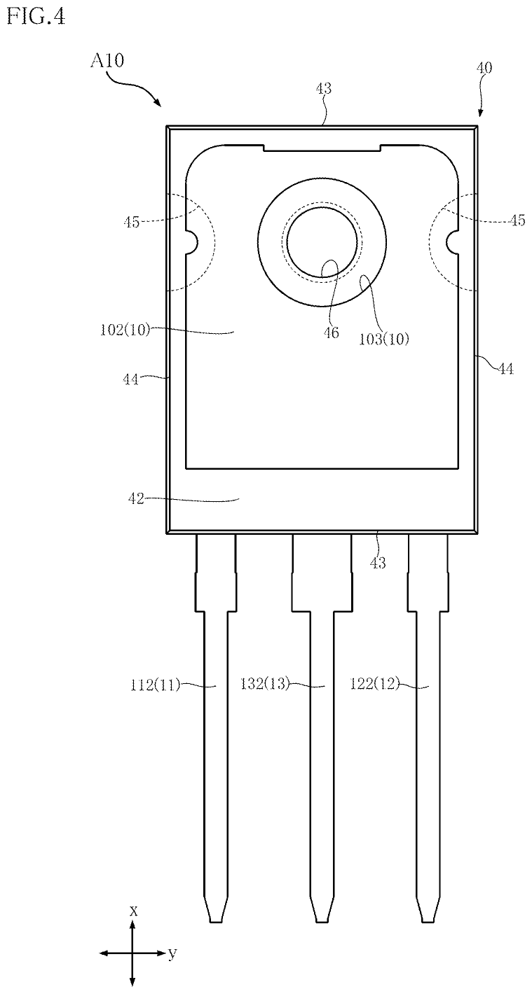

A semiconductor device A10 according to the first embodiment of the present disclosure will be described based on FIGS. 1 to 14. The semiconductor device A10 is used in electronic devices and the like provided with a power converting circuit such as a DC-DC converter. The semiconductor device A10 includes a die pad 10, a first lead 11, a second lead 12, a third lead 13, a semiconductor element 20, a first joining layer 21, a second joining layer 22, a third joining layer 23, a first conductive member 31, a second conductive member 32, and sealing resin 40. In FIG. 3, the sealing resin 40 is shown in a transparent manner to facilitate comprehension. In FIG. 3, the transparent sealing resin 40 is indicated with an imaginary line (two-dot chain line).

For convenience, in the description of the semiconductor device A10, the thickness direction of the die pad 10 is referred to as the “thickness direction z”. The direction that is perpendicular to the thickness direction z is referred to as the “first direction x”. The direction that is perpendicular to both the thickness direction z and the first direction x is referred to as the “second direction y”. As viewed along the thickness direction z, the first direction x corresponds to a direction in which the semiconductor device A10 has a relatively greater length. As viewed along the thickness direction z, the second direction y corresponds to a direction in which the semiconductor device A10 has a relatively smaller length.

As shown in FIGS. 3, and 7 to 9, the die pad 10 is a conductive member onto which the semiconductor element 20 is mounted. The die pad 10 is constituted by the same lead frame as the first lead 11, the second lead 12, and the third lead 13. The lead frame is made of copper (Cu) or a copper alloy. Thus, the compositions of the die pad 10, the first lead 11, the second lead 12, and the third lead 13 each include copper (i.e. each member contains copper). As shown in FIG. 9, the die pad 10 has an obverse surface 101, a reverse surface 102, and a through-hole 103. The obverse surface 101 faces in the thickness direction z. The semiconductor element 20 is mounted onto the obverse surface 101. The reverse surface 102 faces the opposite side to the obverse surface 101 in the thickness direction z. The reverse surface 102 is plated with tin (Sn), for example. The through-hole 103 extends through the die pad 10 in the thickness direction z from the obverse surface 101 to the reverse surface 102. The through-hole 103 is circular as seen in the thickness direction z. As shown in FIG. 7, the thickness T of the die pad 10 is greater than the maximum thickness tₘₐₓ of the first lead 11.

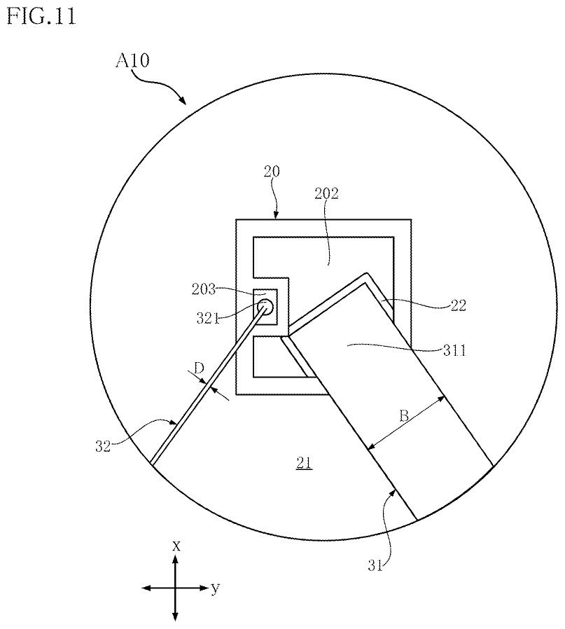

As shown in FIGS. 3 and 7 to 9, the semiconductor element 20 is mounted onto the obverse surface 101 of the die pad 10. The semiconductor element 20 is a vertical-structure MOSFET (Metal-Oxide-Semiconductor Field-Effect Transistor), for example. In the description of the semiconductor device A10, the semiconductor element 20 is an n-channel type, vertical-structure MOSFET. The semiconductor element 20 includes a compound semiconductor substrate. The main material of the compound semiconductor substrate is silicon carbide (SiC). Gallium nitride (GaN) may also be used as the main material of the compound semiconductor substrate. In the semiconductor device A10, the area of the semiconductor element 20, as seen in the thickness direction z, is no more than 40% of the area of the obverse surface 101 of the die pad 10. The area of the semiconductor element 20 as seen in the thickness direction z may be 20% or less or even 10% or less of the area of the obverse surface 101. This ratio can be changed by changing the area of the semiconductor element 20 and the area of the obverse surface 101. As shown in FIGS. 11, 12, and 14, the semiconductor element 20 includes a first electrode 201, a second electrode 202, and a third electrode 203.

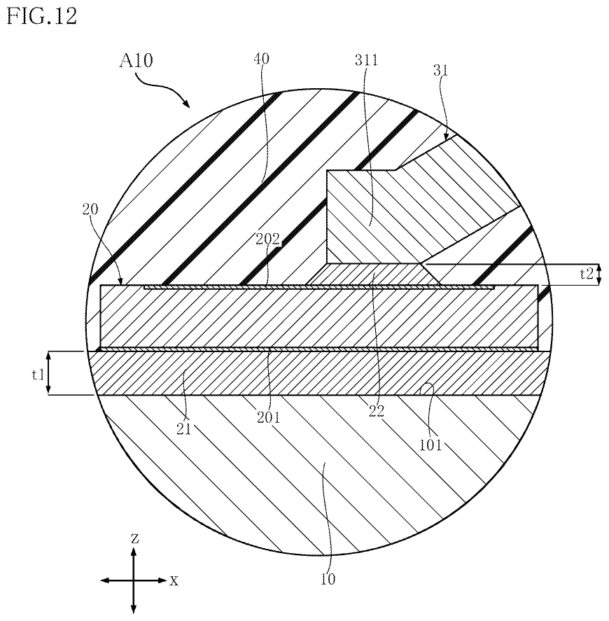

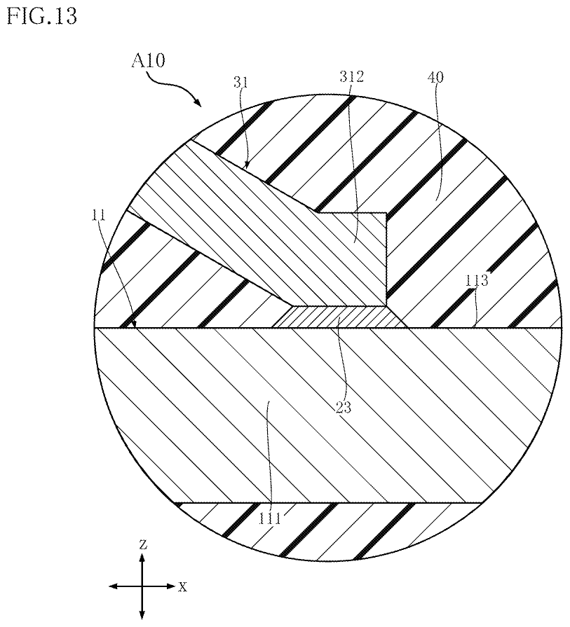

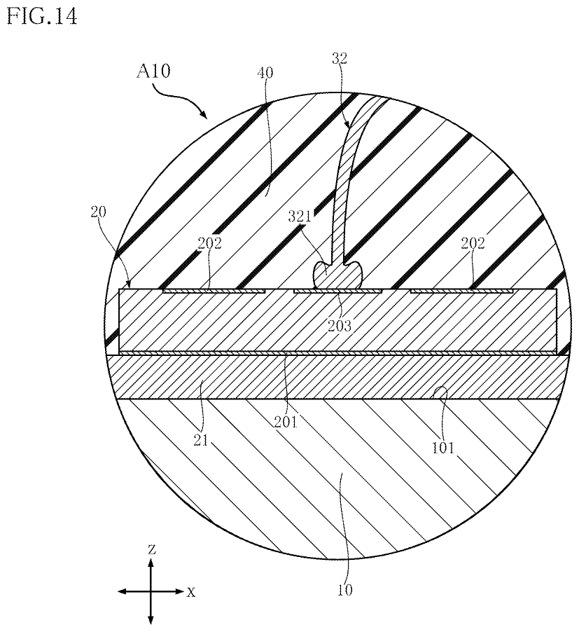

As shown in FIGS. 12 and 14, the first electrode 201 is provided opposing the obverse surface 101 of the die pad 10. The power source voltage of a direct current, which is to undergo power conversion, is applied to the first electrode 201. In other words, the first electrode 201 corresponds to a drain electrode.

As shown in FIGS. 12 and 14, the second electrode 202 is provided on the opposite side to the first electrode 201 in the thickness direction z. Currents converted by the semiconductor element 20 flow to the second electrode 202. In other words, the second electrode 202 corresponds to a source electrode.

As shown in FIGS. 11 and 14, the third electrode 203 is provided on the opposite side to the first electrode 201 in the thickness direction z and is spaced apart from the second electrode 202. A gate voltage for driving the semiconductor element 20 is applied to the third electrode 203. That is, the third electrode 203 corresponds to a gate electrode. Based on the gate voltage, the semiconductor element 20 converts a current corresponding to the power source voltage applied to the first electrode 201. As seen in the thickness direction z, the area of the third electrode 203 is smaller than the area of the second electrode 202.

As shown in FIGS. 12 and 14, the first joining layer 21 includes a portion that is interposed between the obverse surface 101 of the die pad 10 and the first electrode 201 of the semiconductor element 20. The first joining layer 21 is conductive. The first joining layer 21 electrically joins the first electrode 201 and the obverse surface 101 to each other. Accordingly, in the semiconductor device A10, a configuration is employed where the first electrode 201 is electrically joined to the obverse surface 101, as well as being electrically connected to the die pad 10. The first joining layer 21 contains tin. The material of the first joining layer 21 is lead-free solder, for example. The first joining layer 21 may be lead solder.

As shown in FIGS. 3 and 7, the first lead 11 is spaced apart from the die pad 10. The first lead 11 extends along the first direction x. The first lead 11 is electrically connected to the second electrode 202 of the semiconductor element 20. Thus, the first lead 11 corresponds to a source terminal of the semiconductor device A10. The first lead 11 includes a covered portion 111, an exposed portion 112, and a first joining surface 113. The covered portion 111 is covered by the sealing resin 40. The exposed portion 112 is connected to the covered portion 111, and is exposed from the sealing resin 40. The exposed portion 112 extends in the first direction x away from the die pad 10. The surface of the exposed portion 112 is plated with tin, for example. The first joining surface 113 faces the same side as the obverse surface 101 of the die pad 10 in the thickness direction z. The first joining surface 113 is a portion of the covered portion 111. In the thickness direction z, the first joining surface 113 is positioned closer to the semiconductor element 20 than to the obverse surface 101.

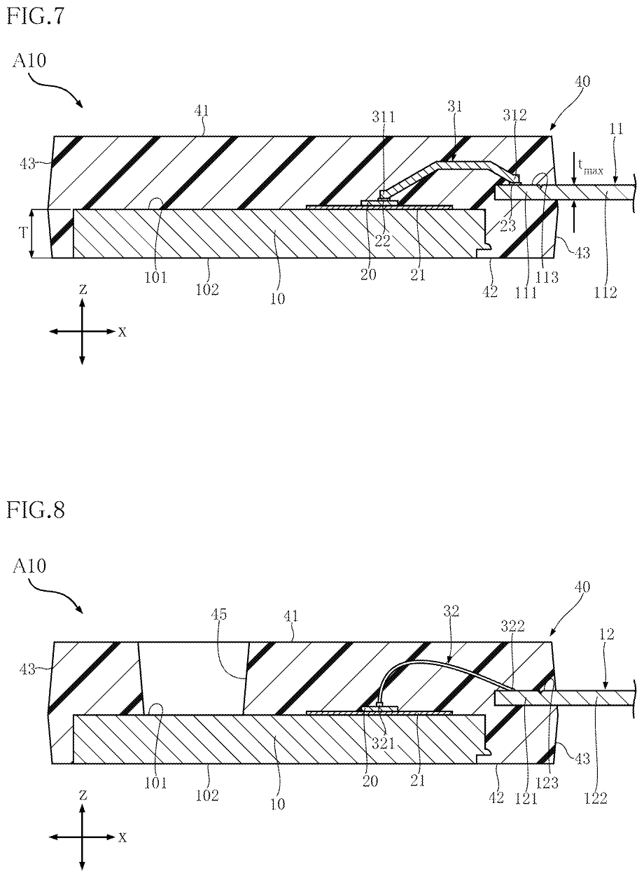

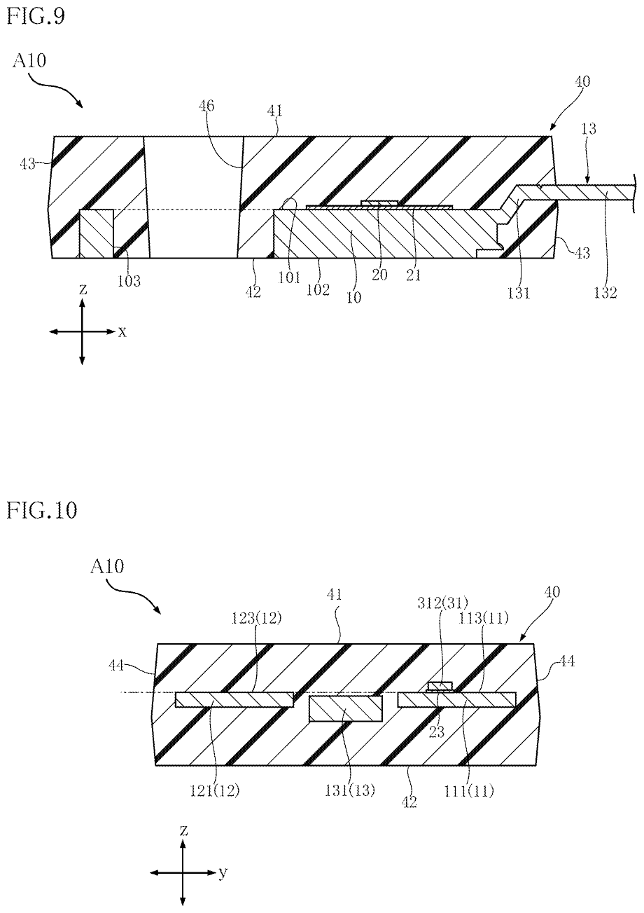

As shown in FIGS. 3 and 8, the second lead 12 is spaced apart from both the die pad 10 and the first lead 11. The second lead 12 extends along the first direction x. In the semiconductor device A10, the second lead 12 is located on the opposite side to the first lead 11 in the second direction y, relative to the third lead 13. The second lead 12 is electrically connected to the third electrode 203 of the semiconductor element 20. Thus, the second lead 12 corresponds to a gate terminal of the semiconductor device A10. The second lead 12 includes a covered portion 121, an exposed portion 122, and a second joining surface 123. The covered portion 121 is covered by the sealing resin 40. The exposed portion 122 is connected to the covered portion 121 and is exposed from the sealing resin 40. The exposed portion 122 extends in the first direction x away from the die pad 10. The surface of the exposed portion 122 is plated with tin. The second joining surface 123 faces the same side as the obverse surface 101 of the die pad 10 in the thickness direction z. The second joining surface 123 is a portion of the covered portion 121. In the thickness direction z, the second joining surface 123 is positioned closer to the semiconductor element 20 than to the obverse surface 101. As shown in FIG. 10, the position of the second joining surface 123 is the same as the position of the first joining surface 113 of the first lead 11 in the thickness direction z.

As shown in FIGS. 3 and 9, the third lead 13 includes a portion extending in the first direction x and is connected to the die pad 10. The third lead 13 is made of the same material as the die pad 10. The third lead 13 includes a covered portion 131 and an exposed portion 132. The covered portion 131 is connected to the die pad 10 and is covered by the sealing resin 40. The covered portion 131 is bent as viewed along the second direction y. The exposed portion 132 is connected to the covered portion 131 and is exposed from the sealing resin 40. The exposed portion 132 extends in the first direction x away from the die pad 10. The surface of the exposed portion 132 is plated with tin.

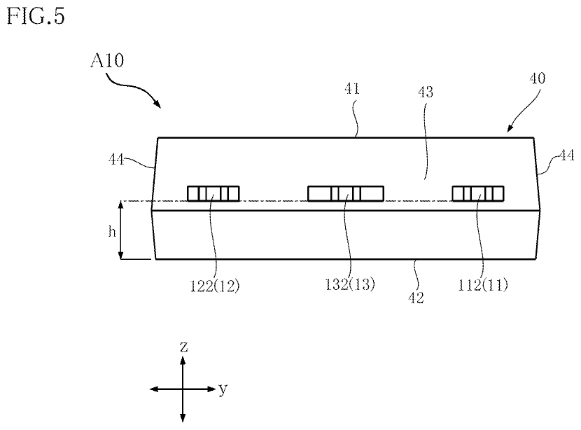

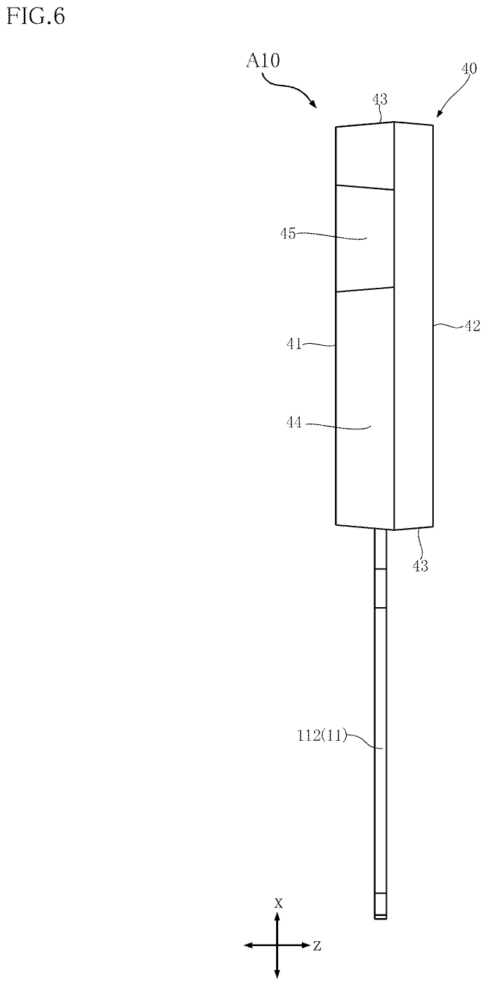

As shown in FIG. 5, in the semiconductor device A10, the heights h of the exposed portion 112 of the first lead 11, the exposed portion 122 of the second lead 12, and the exposed portion 132 of the third lead 13 are all the same. Thus, at least a portion (the exposed portion 132) of the third lead 13 overlaps with the first lead 11 and the second lead 12 as viewed along the second direction y (see FIG. 6).

As shown in FIGS. 3 and 7, the first conductive member 31 is electrically joined to the second electrode 202 of the semiconductor element 20 and the first joining surface 113 of the first lead 11. Accordingly, the first lead 11 is electrically connected to the second electrode 202. The first conductive member 31 contains copper. In the semiconductor device A10, the first conductive member 31 is a metal clip with a predetermined length. As shown in FIGS. 12 and 13, the first conductive member 31 includes a first joining portion 311 and a second joining portion 312. The first joining portion 311 is a portion located at one end of the first conductive member 31, and electrically joins the first conductive member 31 to the second electrode 202. The second joining portion 312 is a portion located at the other end of the first conductive member 31, and electrically joins the first conductive member 31 to the first joining surface 113.

As shown in FIG. 12, the second joining layer 22 includes a portion interposed between the second electrode 202 of the semiconductor element 20 and the first joining portion 311 of the first conductive member 31. The second joining layer 22 is conductive. The second joining layer 22 electrically joins the first joining portion 311 and the second electrode 202 to each other. Accordingly, in the semiconductor device A10, a configuration is employed where the first conductive member 31 is electrically joined to the second electrode 202 as well as being electrically connected to the second electrode 202. The second joining layer 22 contains tin. The second joining layer 22 is made of the same material as the first joining layer 21. Furthermore, the thickness t1 of the first joining layer 21 is greater than the thickness t2 of the second joining layer 22.

As shown in FIG. 13, the third joining layer 23 includes a portion that is interposed between the first joining surface 113 of the first lead 11 and the second joining portion 312 of the first conductive member 31. The third joining layer 23 is conductive. The third joining layer 23 electrically joins the second joining portion 312 and the first joining surface 113 to each other. Accordingly, in the semiconductor device A10, a configuration is employed where the first conductive member 31 is electrically joined to the first joining layer 113 as well as being electrically connected to the first lead 11. The third joining layer 23 is made of the same material as the first joining layer 21.

As shown in FIGS. 3 and 8, the second conductive member 32 is electrically joined to the third electrode 203 of the semiconductor element 20 and the second joining surface 123 of the second lead 12. Accordingly, the second lead 12 is electrically connected to the third electrode 203. The second conductive member 32 contains aluminum (Al). In the semiconductor device A10, the second conductive member 32 is a wire. The second conductive member 32 is formed through wire bonding. As shown in FIG. 8, the second conductive member 32 has a third joining portion 321 and a fourth joining portion 322. As shown in FIG. 14, the third joining portion 321 is a portion that is located at one end of the second conductive member 32 and electrically joins the second conductive member 32 to the third electrode 203. When the second conductive member 32 is formed through wire bonding, the third joining portion 321 corresponds to the starting point of the bonding. The fourth joining portion 322 is a portion that is located at the other end of the second conductive member 32 and electrically joins the second conductive member 32 to the second joining surface 123. When the second conductive member 32 is formed through wire bonding, the fourth joining portion 322 corresponds to an end point of the bonding.

Differences between the first conductive member 31 and the second conductive member 32 are described below. The Young's modulus of the second conductive member 32 is smaller than the Young's modulus of the first conductive member 31. This is based on the first conductive member 31 containing copper and the second conductive member 32 containing aluminum, as described above. Thus, the linear expansion coefficient of the second conductive member 32 is greater than the linear expansion coefficient of the first conductive member 31. Also, the thermal conductivity of the second conductive member 32 is smaller than the thermal conductivity of the first conductive member 31. Furthermore, as shown in FIG. 11, the width B of the first conductive member 31 is greater than the width (diameter) D of the second conductive member 32.

As shown in FIGS. 3 and 7 to 10, the sealing resin 40 covers the semiconductor element 20, the first conductive member 31, and the second conductive member 32, and portions of the die pad 10, the first lead 11, the second lead 12, and the third lead 13. The sealing resin 40 has electric insulating properties. The sealing resin 40 is made of a material including a black epoxy resin, for example. The sealing resin 40 includes a top surface 41, a bottom surface 42, a pair of first side surfaces 43, a pair of second side surfaces 44, a pair of openings 45, and an attachment hole 46.

As shown in FIGS. 7 to 10, the top surface 41 faces the same side as the obverse surface 101 of the die pad 10 in the thickness direction z. As shown in FIGS. 7 to 9, the bottom surface 42 faces the opposite side to the top surface 41 in the thickness direction z. The reverse surface 102 of the die pad 10 is exposed from the bottom surface 42.

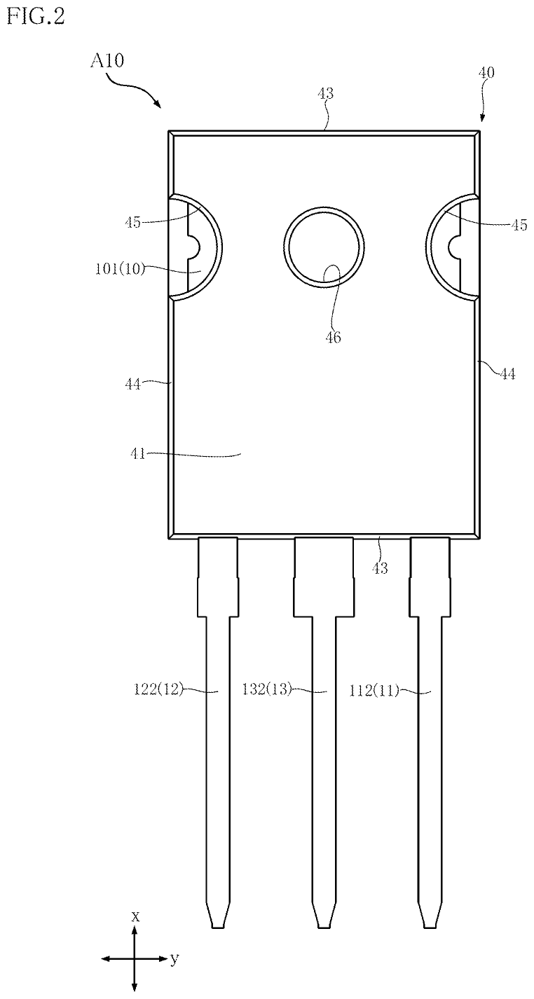

As shown in FIGS. 2, 4, and 6, the pair of first side surfaces 43 are spaced apart from each other in the first direction x. The pair of first side surfaces 43 are connected to the top surface 41 and the bottom surface 42. As shown in FIG. 5, the exposed portion 112 of the first lead 11, the exposed portion 122 of the second lead 12, and the exposed portion 132 of the third lead 13 are exposed from one first side surface 43 of the pair of first side surfaces 43.

As shown in FIGS. 2, 4, and 5, the pair of second side surfaces 44 are spaced apart from each other in the second direction y. The pair of second side surfaces 44 are connected to the top surface 41 and the bottom surface 42. As shown in FIGS. 2, 6, and 8, the pair of openings 45 are spaced apart from each other in the second direction y. Each opening 45 is depressed to the inner side of the sealing resin 40 from the top surface 41 and the corresponding one of the pair of second side surfaces 44. Portions of the obverse surface 101 of the die pad 10 are exposed from the pair of openings 45. As shown in FIGS. 2, 4, and 9, the attachment hole 46 extends through the sealing resin 40 in the thickness direction z, from the top surface 41 to the bottom surface 42. As viewed along the thickness direction z, the attachment hole 46 is enclosed by the through-hole 103 of the die pad 10. The circumferential surface of the die pad 10 that defines the through-hole 103 is covered by the sealing resin 40. Accordingly, as viewed along the thickness direction z, the largest size of the attachment hole 46 is smaller than the size of the through-hole 103.

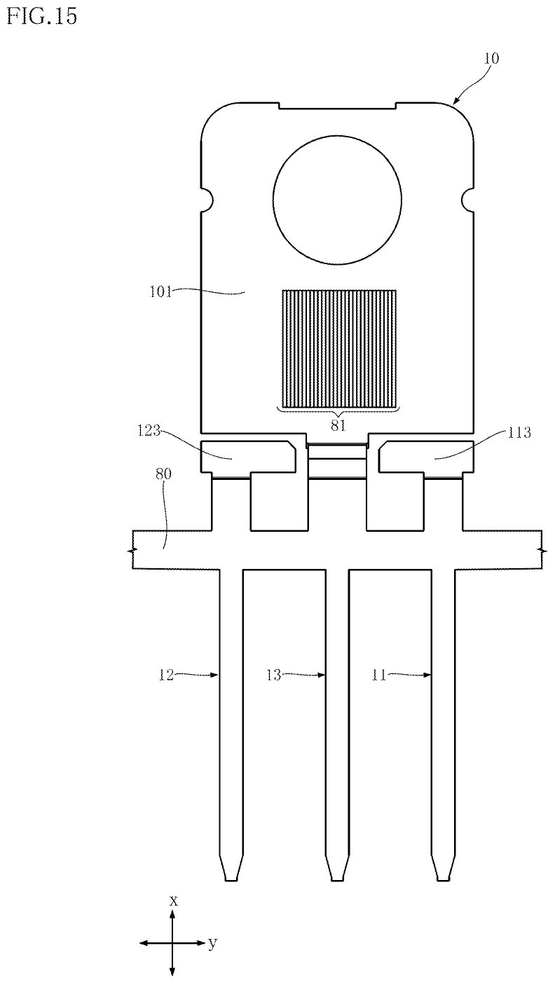

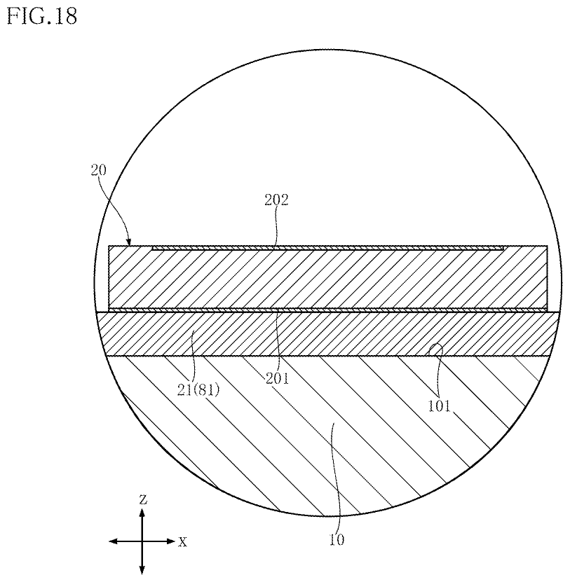

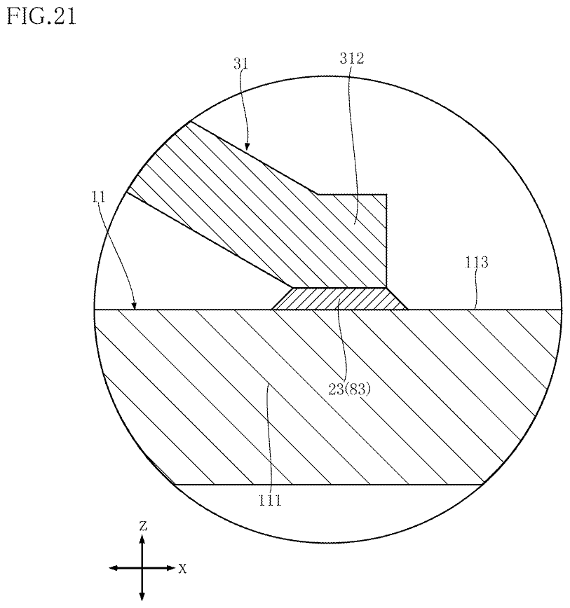

Next, an example of the method for manufacturing the semiconductor device A10 will be described based on FIGS. 15 to 23. The position of the cross-sections in FIGS. 18 and 20 is the same as that of the cross-section in FIG. 12. The position of the cross-section in FIG. 21 is the same as that of the cross-section in FIG. 13.

First, as shown in FIG. 15, a first joining material 81 is disposed on the obverse surface 101 of the die pad 10. The first lead 11, the second lead 12, and the third lead 13 are linked to each other by a tie bar 80 constituting a lead frame. The tie bar 80 extends along the second direction y. The first joining material 81 is conductive. The first joining material 81 is a cream solder or wire solder. If the first joining material 81 is a wire solder, the first joining material 81 is tacked onto the obverse surface 101.

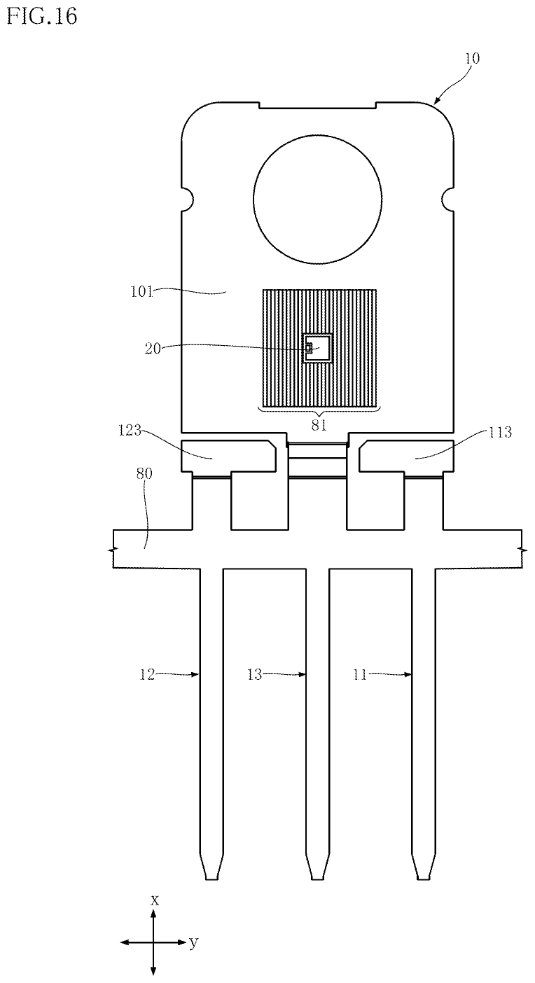

Next, as shown in FIG. 16, the semiconductor element 20 is disposed on the first joining material 81. At this time, the first electrode 201 of the semiconductor element 20 opposes the first joining material 81. If the first joining material 81 is wire solder, the first electrode 201 is tacked onto the first joining material 81.

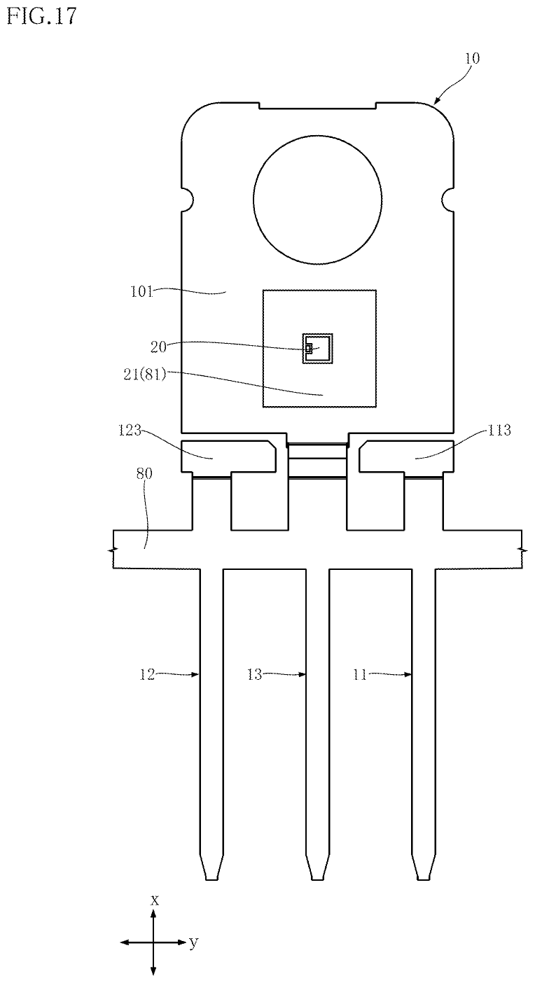

Then, as shown in FIGS. 17 and 18, after the first joining material 81 has been melted through reflow, the melted first joining material 81 is cooled to solidify, and thus the first electrode 201 of the semiconductor element 20 is electrically joined to the obverse surface 101 of the die pad 10. In this step, the first joining material 81 solidified through cooling becomes the first joining layer 21.

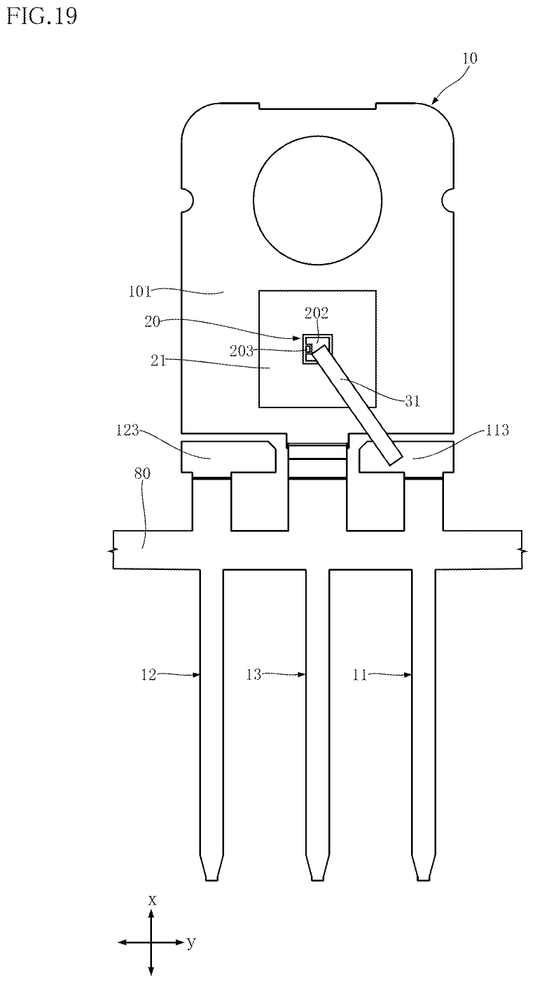

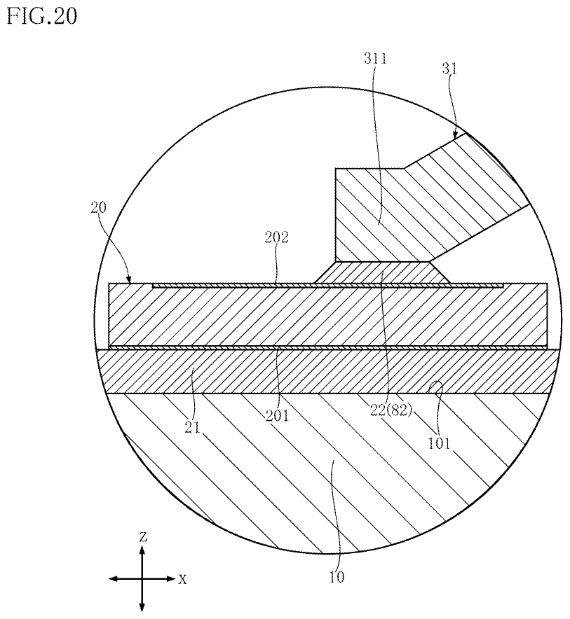

Next, as shown in FIGS. 20 and 21, a second joining material 82 is disposed on the second electrode 202 of the semiconductor element 20 and a third joining material 83 is disposed on the first joining surface 113 of the first lead 11. The second joining material 82 and the third joining material 83 are each made of the same material as the first joining material 81. The second joining material 82 and the third joining material 83 are conductive. If the second joining material 82 and the third joining material 83 are each cream solder, a dispenser or the like is used when disposing them. Thereafter, the first conductive member 31 is electrically joined to the second electrode 202 and the first joining surface 113 through clip bonding. In the clip bonding, the first joining portion 311 of the first conductive member 31 is disposed on the second joining material 82. Also, the second joining portion 312 of the first conductive member 31 is disposed on the third joining material 83. Then, after the second joining material 82 and the third joining material 83 have been melted through reflow, the melted second joining material 82 and the third joining material 83 are cooled to solidify, and thus the first joining portion 311 is electrically joined to the second electrode 202. Also, the second joining portion 312 is electrically joined to the first joining surface 113. Thus, as shown in FIG. 19, the first conductive member 31 is electrically joined to the second electrode 202 and the first joining surface 113. In this step, the second joining material 82 solidified through cooling becomes the second joining layer 22. Also, the third joining material 83 solidified through cooling becomes the third joining layer 23.

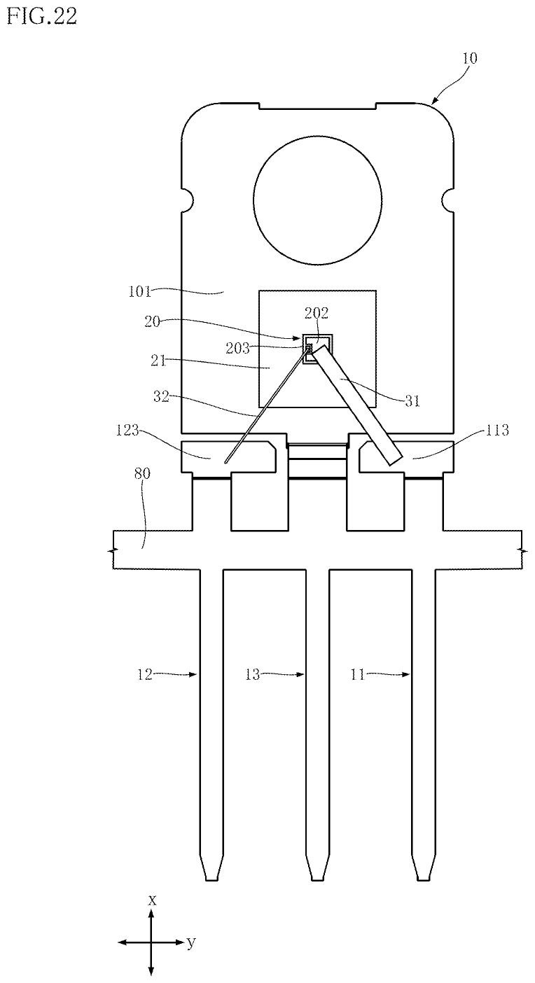

As shown in FIG. 22, the second conductive member 32 is electrically joined to the third electrode 203 of the semiconductor element 20 and the second joining surface 123 of the second lead 12. In this step, the second conductive member 32 is electrically joined to the third electrode 203 and the second joining surface 123 through wire bonding. Thus, the second conductive member 32 is formed through this wire bonding.

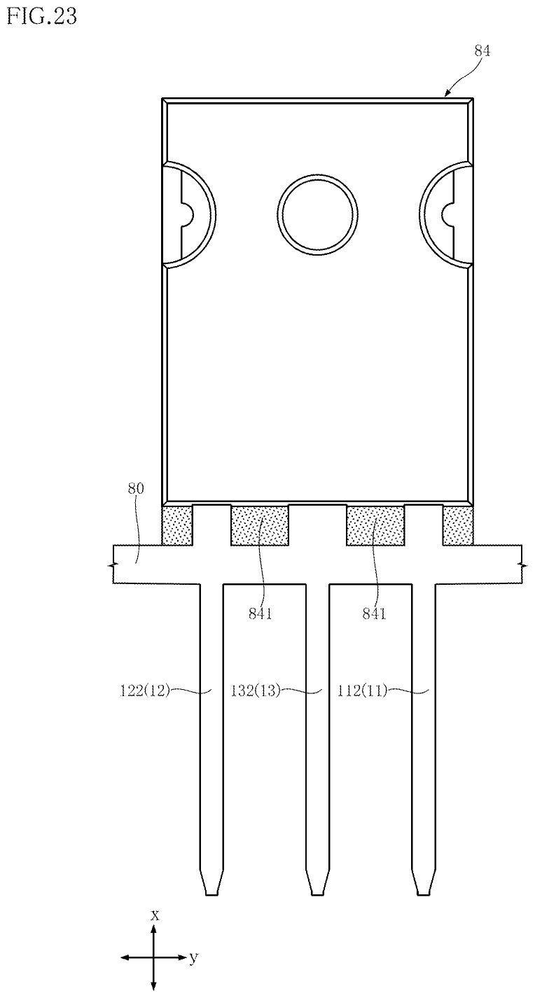

Next, as shown in FIG. 23, sealing resin 84 is formed covering the semiconductor element 20, the first conductive member 31, and the second conductive member 32, and portions of the die pad 10, the first lead 11, the second lead 12, and the third lead 13. The sealing resin 84 is formed through transfer molding. Accompanying the formation of the sealing resin 84, resin burrs 841 are formed. The resin burrs 841 are contained by the exposed portion 112 of the first lead 11, the exposed portion 122 of the second lead 12, the exposed portion 132 of the third lead 13, and the tie bar 80. Thereafter, the resin burrs 841 are removed using high-pressure water or the like. Then, the surfaces of the exposed portion 112 of the first lead 11, the exposed portion 122 of the second lead 12, and the exposed portion 132 of the third lead 13 and the reverse surface 102 of the die pad 10 are covered with a tin plating through electroplating in which the die bar 80 acts as a conductive path. Lastly, the semiconductor device A10 is obtained by cutting the tie bar 80.

Next, the operation and effects of the semiconductor device A10 will be described.

The semiconductor device A10 is provided with the first joining layer 21, the first conductive member 31, and the second conductive member 32. The first joining layer 21 is conductive and is electrically joined to the first electrode 201 of the semiconductor element 20 and the obverse surface 101 of the die pad 10. The first conductive member 31 is electrically joined to the second electrode 202 of the semiconductor element 20. The second conductive member 32 is electrically joined to the third electrode 203 of the semiconductor element 20. As viewed along the thickness direction z, the area of the third electrode 203 is smaller than the area of the second electrode 202. Furthermore, the Young's modulus of the second conductive member 32 is smaller than the Young's modulus of the first conductive member 31.

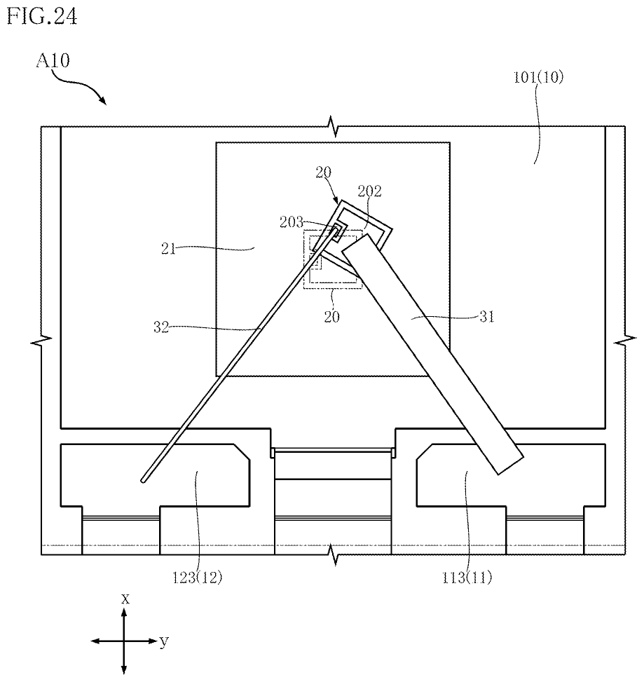

Here, in the manufacturing steps of the semiconductor device A10 shown in FIGS. 17 and 18, when the first joining material 81 forming the first joining layer 21 is melted, there are cases where the position of the semiconductor element 20 is shifted relative to the die pad 10, as shown in FIG. 24. As a result, the positions of the second electrode 202 and the third electrode 203 in the semiconductor element 20 are shifted from where they should be. In this case, because the area of the second electrode 202 is comparatively large as viewed along the thickness direction z, the joining state of the first conductive member 31 to the second electrode 202 can kept in a favorable state. However, the area of the third electrode 203 is smaller than the area of the second electrode 202 as viewed along the thickness direction z, and thus, when the second conductive member 32 is a metal clip with a predetermined length, the joining area of the second conductive member 32 to the third electrode 203 may be reduced by an extreme amount. Thus, in the manufacturing step of the semiconductor device A10 shown in FIG. 22, the second conductive member 32 is formed through wire bonding. Accordingly, the third electrode 203 that has been positionally shifted is aimed for and the second conductive member 32, which is a wire, is accurately joined, and thus a reduction in the surface area of the second conductive member 32 to the third electrode 203 can be avoided. Accordingly, even if the position of the semiconductor element 20 is shifted relative to the die pad 10, the joining state between the third electrode 203 and the second conductive member 32 is favorable. In this state, the Young's modulus of the second conductive member 32 is smaller than the Young's modulus of the first conductive member 31, and the impact force acting on the third electrode 203 accompanying formation of the second conductive member 32 can be reduced. Based on the above, with the semiconductor device A10, the joining state of conductive members (the first conductive member 31 and the second conductive member 32) to each electrode (the second electrode 202 and the third electrode 203) of the semiconductor element 20 can be improved while being able to support a larger current.

The first conductive member 31 contains copper. Accordingly, compared to an aluminum wire, the electric resistance of the first conductive member 31 can be reduced. This is favorable for allowing larger currents to flow through the semiconductor element 20.

The linear expansion coefficient of the second conductive member 32 is greater than the linear expansion coefficient of the first conductive member 31. Conversely, the thermal conductivity of the second conductive member 32 is smaller than the thermal conductivity of the first conductive member 31. Accordingly, when using the semiconductor device A10, heat generated by the semiconductor 20 is more likely to be conducted by the second electrode 202 than the third electrode 203. Thus, thermal stress at the interface between the third electrode 203 and the second conductive member 32 can be reduced while suppressing an increase in the on-resistance of the third electrode 203.

The thickness t1 of the first joining layer 21 is greater than the thickness t2 of the second joining layer 22. Accordingly, when the semiconductor device A10 is being used, heat generated by the semiconductor element 20 can be more quickly conveyed to the die pad 10. Furthermore, in the manufacturing process of the semiconductor device A10, as a result of using wire solder for the first joining material 81, a first joining layer 21 with a constant thickness can be formed.

In the thickness direction z, the first joining surface 113 of the first lead 11 is positioned closer to the semiconductor element 20 than to the obverse surface 101 of the die pad 10. Accordingly, the length of the first conductive member 31 is reduced, and thus the inductance of the first conductive member 31 can be reduced.

In the thickness direction z, the second joining surface 123 of the second lead 12 is positioned closer to the semiconductor element 20 than to the obverse surface 101 of the die pad 10. Accordingly, the length of the second conductive member 32 is reduced, and thus the inductance of the second conductive member 32 can be reduced. This is favorable for reducing the on-resistance of the third electrode 203 of the semiconductor element 20.

The die pad 10 contains copper. Furthermore, the thickness T of the die pad 10 is greater than the tₘₐₓ of the first lead 11. Accordingly, the efficiency of thermal conduction in a direction perpendicular to the thickness direction z can be improved while improving the thermal conductivity of the die pad 10. This contributes to an increase in the heat dissipation of the die pad 10.

The semiconductor device A10 includes the sealing resin 40 that covers the semiconductor element 20, the first conductive member 31, and the second conductive member 32, and a portion of the die pad 10. The reverse surface 102 of the die pad 10 is exposed from the sealing resin 40. Accordingly, a reduction in the heat dissipation of the semiconductor device A10 can be avoided while protecting the semiconductor element 20, the first conductive member 31, and the second conductive member 32 from the outside.

The semiconductor device A10 also includes the second joining layer 22 and the third joining layer 23. The second joining layer 22 is conductive and is electrically joined to the first conductive member 31 and the second electrode 202 of the semiconductor element 20. The third joining layer 23 is conductive and electrically joins the first conductive member 31 and the first joining surface 113 of the first lead 11 to each other. The second joining layer 22 and the third joining layer 23 are each made of the same material as the first joining layer 21 that contains tin. Accordingly, in the manufacturing steps of the semiconductor device A10 shown in FIGS. 20 and 21, when the second joining material 82 forming the second joining layer 22 is melted, the third joining material 83 forming the third joining layer 23 is simultaneously melted. Accordingly, in manufacturing the semiconductor device A10, when the first conductive member 31 is electrically joined to the second electrode 202, the first conductive member 31 can also be electrically joined to the first joining surface 113 at the same time, and thus the manufacturing efficiency of the semiconductor device A10 can be improved.

The present disclosure is not limited to the aforementioned embodiments or variations. The specific configuration of each portion of the present disclosure can be freely designed in various ways.

The present disclosure includes the configurations described in the following clauses.

Clause 1.

A semiconductor device including:

a die pad that has an obverse surface facing in a thickness direction;

a semiconductor element that has a first electrode provided opposing the obverse surface, and a second electrode and a third electrode that are provided opposite to the first electrode in the thickness direction and are spaced apart from each other, the first electrode being electrically joined to the obverse surface;

a first joining layer that electrically joins the first electrode and the obverse surface to each other;

a first conductive member electrically joined to the second electrode; and

a second conductive member electrically joined to the third electrode,

in which the area of the third electrode is smaller than the area of the second electrode as viewed along the thickness direction, and

the Young's modulus of the second conductive member is smaller than the Young's modulus of the first conductive member.

Clause 2.

The semiconductor device according to clause 1, in which the first joining layer contains tin.

Clause 3.

The semiconductor device according to clause 2, further including a second joining layer that electrically joins the first conductive member and the second electrode to each other,

in which the second joining layer is made of the same material as the first joining layer.

Clause 4.

The semiconductor device according to clause 3, in which the linear expansion coefficient of the second conductive member is greater than the linear expansion coefficient of the first conductive member.

Clause 5.

The semiconductor device according to clause 4, in which the thermal conductivity of the second conductive member is smaller than the thermal conductivity of the first conductive member.

Clause 6.

The semiconductor device according to clause 5, in which the width of the first conductive member is greater than the width of the second conductive member.

Clause 7.

The semiconductor device according to any one of clauses 4 to 6,

in which the first conductive member contains copper, and

the second conductive member contains aluminum.

Clause 8.

The semiconductor device according to any one of clauses 4 to 7, in which the area of the semiconductor element is 40% or less of the area of the obverse surface as viewed along the thickness direction.

Clause 9.

The semiconductor device according to clause 8, in which the semiconductor element includes a compound semiconductor substrate.

Clause 10.

The semiconductor device according to any one of clauses 3 to 9, further including:

a first lead that has a first joining surface that faces the same side as the obverse surface in the thickness direction and is spaced apart from the die pad; and

a third joining layer that electrically joins the first conductive member and the first joining surface to each other,

in which the first lead contains copper, and

the third joining layer is made of the same material as the first joining layer.

Clause 11.

The semiconductor device according to clause 10, in which, in the thickness direction, the first joining surface is positioned closer to the semiconductor element than to the obverse surface.

Clause 12.

The semiconductor device according to clause 11, in which the thickness of the die pad is greater than the maximum thickness of the first lead.

Clause 13.

The semiconductor device according to any one of clauses 10 to 12, further including a second lead that has a second joining surface that faces the same side as the obverse surface in the thickness direction, and is spaced apart from both the die pad and the first lead,

in which the second conductive member is electrically joined to the second joining surface.

Clause 14.

The semiconductor device according to clause 13, in which, in the thickness direction, the second joining surface is positioned closer to the semiconductor element than to the obverse surface.

Clause 15.

The semiconductor device according to clause 13 or 14, in which the first lead and the second lead each extend along a first direction that is perpendicular to the thickness direction,

the semiconductor device further including a third lead that includes a portion that extends along the first direction and is connected to the die pad,

the material of the third lead is the same material as the die pad, and

at least a portion of the third lead overlaps with the first lead and the second lead as viewed along a second direction that is perpendicular to both the thickness direction and the first direction.

Clause 16.

The semiconductor device according to any one of clauses 1 to 15, further including sealing resin that covers the semiconductor element, the first conductive member, and the second conductive member, and a portion of the die pad,

in which the die pad has a reverse surface that faces the opposite side to the obverse surface in the thickness direction, and

the reverse surface is exposed from the sealing resin.

Clause 17.

A method of manufacturing a semiconductor device including the steps of:

disposing a conductive joining material on an obverse surface of a die pad, the obverse surface facing in a thickness direction;

disposing a semiconductor element on the joining material, the semiconductor element including a first electrode, a second electrode and a third electrode, the first electrode and the second electrode being opposite to each other in the thickness direction, the third electrode being on the same side as the second electrode in the thickness direction but spaced apart from the second electrode, the first electrode facing the joining material;

electrically joining the first electrode to the obverse surface by melting and solidifying the joining material;

electrically joining the first conductive member to the second electrode; and

electrically joining the second conductive member to the third electrode,

in which the area of the third electrode is smaller than the area of the second electrode as viewed along the thickness direction, and

the Young's modulus of the second conductive member is smaller than the Young's modulus of the first conductive member.

Clause 18.

The method of manufacturing a semiconductor device according to clause 17, in which, in electrically joining the first conductive member, the first conductive member is electrically joined to the second electrode through clip bonding using the same joining material as the joining material, and

in electrically joining the second conductive member, the second conductive member is electrically joined to the third electrode by wire bonding.

Clause 19.

The method of manufacturing a semiconductor device according to clause 18, in which the joining material is a wire solder.

### REFERENCE NUMERALS

A10: Semiconductor device 10: Die pad 101: Obverse surface
102: Reverse surface 103: Through-hole 11: First lead
111: Covered portion 112: Exposed portion
113: First joining surface 12: Second lead
121: Covered portion 122: Exposed portion
123: Second joining surface 13: Third lead
131: Covered portion 132: Exposed portion
19: Plating layer 20: Semiconductor element
201: First electrode 202: Second electrode
203: Third electrode 21: First joining layer
22: Second joining layer 23: Third joining layer
31: First conductive member 311: First joining portion
312: Second joining portion 32: Second conductive member
321: Third joining portion 322: Fourth joining portion
40: Sealing resin 41: Top surface
42: Bottom surface 43: First side surface
44: Second side surface 45: Opening
46: Attachment hole 80: Tie bar
81: First joining material 82: Second joining material
83: Third joining material z: Thickness direction
x: First direction y: Second direction

1. A semiconductor device comprising:
a die pad that has an obverse surface facing in a thickness direction;
a semiconductor element that has a first electrode opposing the obverse surface, and a second electrode and a third electrode that are opposite to the first electrode in the thickness direction and are spaced apart from each other, the first electrode being electrically joined to the obverse surface;
a first joining layer that electrically joins the first electrode and the obverse surface to each other;
a first conductive member electrically joined to the second electrode; and
a second conductive member electrically joined to the third electrode,
wherein the third electrode is smaller in area than the second electrode as viewed along the thickness direction, and
the second conductive member is smaller in Young's modulus than the first conductive member.

2. The semiconductor device according to claim 1, wherein the first joining layer contains tin.

3. The semiconductor device according to claim 2, further comprising a second joining layer that electrically joins the first conductive member and the second electrode to each other,
wherein the second joining layer is made of a same material as the first joining layer.

4. The semiconductor device according to claim 3, wherein the second conductive member is greater in linear expansion coefficient than the first conductive member.

5. The semiconductor device according to claim 4, wherein the second conductive member is smaller in thermal conductivity than the first conductive member.

6. The semiconductor device according to claim 5, wherein the first conductive member is greater in width than the second conductive member.

7. The semiconductor device according to claim 4, wherein the first conductive member contains copper, and
the second conductive member contains aluminum.

8. The semiconductor device according to claim 4, wherein an area of the semiconductor element is 40% or less of an area of the obverse surface as viewed along the thickness direction.

9. The semiconductor device according to claim 3, further comprising:
a first lead that has a first joining surface facing a same side as the obverse surface in the thickness direction, the first lead being spaced apart from the die pad; and
a third joining layer that electrically joins the first conductive member and the first joining surface to each other,
wherein the first lead contains copper, and
the third joining layer is made of a same material as the first joining layer.

10. The semiconductor device according to claim 9, wherein, in the thickness direction, the first joining surface is closer to the semiconductor element than to the obverse surface.

11. The semiconductor device according to claim 10, wherein a thickness of the die pad is greater than a maximum thickness of the first lead.

12. The semiconductor device according to claim 9, further comprising a second lead that has a second joining surface facing a same side as the obverse surface in the thickness direction, the second lead being spaced apart from both the die pad and the first lead,
wherein the second conductive member is electrically joined to the second joining surface.

13. The semiconductor device according to claim 12, wherein, in the thickness direction, the second joining surface is closer to the semiconductor element than to the obverse surface.

14. The semiconductor device according to claim 1, further comprising a sealing resin that covers the semiconductor element, the first conductive member, and the second conductive member, and a portion of the die pad,
wherein the die pad has a reverse surface opposite to the obverse surface in the thickness direction, and
the reverse surface is exposed from the sealing resin.

15. A method of manufacturing a semiconductor device comprising:
disposing a conductive joining material on a die pad that has an obverse surface facing in a thickness direction;
disposing a semiconductor element on the joining material, the semiconductor element including a first electrode, a second electrode and a third electrode, the first electrode and the second electrode being opposite to each other in the thickness direction, the third electrode being disposed on a same side as the second electrode in the thickness direction and spaced apart from the second electrode, the first electrode facing the joining material;
electrically joining the first electrode to the obverse surface by melting and solidifying the joining material;
electrically joining the first conductive member to the second electrode; and
electrically joining the second conductive member to the third electrode,
wherein the third electrode is smaller in area than the second electrode as viewed along the thickness direction, and
the second conductive member is smaller in Young's modulus than the first conductive member.
